(19) United States
(12) Patent Application Publication
(10) Pub. No.: US 2026/0354096 A1
(43) Pub. Date: Nov. 5, 2026

(54) SUBSTRATE HANDLING ASSEMBLY AND SUBSTRATE HANDLING SYSTEM

(71) Applicant: Gudeng Precision Industrial Co., LTD., New Taipei City (TW)

(72) Inventors: Ming-Chien Chiu, New Taipei City (TW); Yung-Chin Pan, New Taipei City (TW); Po-Ting Lee, New Taipei City (TW)

(21) Appl. No.: 19/660,665

(22) Filed: Apr. 28, 2026

Related U.S. Application Data
(60) Provisional application No. 63/798,652, filed on May 2, 2025.

(51) Int. Cl. H10P 72/10; H10P 72/50; H10P 72/78

(52) U.S. Cl. CPC H10P 72/1921; H10P 72/1922; H10P 72/50; H10P 72/78

(57) ABSTRACT

A substrate handling assembly and a substrate handling system include a support member and a handling mechanism. The support member is configured to be disposed inside a container body of a substrate container and configured to support a substrate unit. The support member includes a clearance portion. The handling mechanism includes a transfer portion and a limiting structure. The transfer portion is movable into and out of the container body and is configured to pick and place the substrate unit in a first axial direction. The limiting structure is disposed on the transfer portion and is configured to positionally limit the substrate unit in a second axial direction. The clearance portion and the limiting structure are structurally complementary to avoid mechanical interference therebetween.

### RELATED APPLICATIONS

This application claims priority to U.S. Provisional Patent Application, No. US 63/798,652, by CHIU, et al., titled “SUBSTRATE HANDLING ASSEMBLY,” filed on May. 02, 2025, which is hereby incorporated by reference in their entirety.

### BACKGROUND OF THE INVENTION

### Technical Field

The present disclosure relates to a substrate handling assembly and a substrate handling system. More particularly, the present disclosure relates to a substrate handling assembly and a substrate handling system adapted for use in the semiconductor field.

### Description of Related Art

In the semiconductor industry, a wide variety of substrates are used in the fabricating process related to semiconductor components. Substrate containers are used to accommodate the substrates and protect them from collisions and environmental pollutions. One known substrate container involves stacking substrates on holding trays within the substrate container, which facilitates the transfer of the substrate in relation to the container.

In response to the advancements in the semiconductor industry, the automated retrieval of workpieces has become a key requirement for different manufactures, to reduce labor costs and increase the yield rate. On one hand, the holding trays are configured to be compatible with the automated transferring systems like OHT (Overhead Hoist Transport) systems and load port equipment and are designed to be handled by robotic arms. On the other hand, multiple supporters are known to be employed in substrate containers to support and fix the stacked holding trays and substrates.

Normally, the stacked holding trays and substrates are placed into substrate containers like FOUPs (Front Opening Unified Pods), resulting in significant overall height and weight. The presence of the supporters restricts the access of the robotic arm to the front and back of the holding trays. This limited access can lead to deviation or wobbling of the stack, and in worse cases, the stack will collapse.

Therefore, there exists a need for a more stable and efficient approach to handling the substrates in the substrate container.

### SUMMARY

In view of the above-mentioned problems, the present disclosure provides a substrate handling assembly and a substrate handling system, which can stably pick, place, and handle a substrate unit, thereby reducing the risk of stack collapse and improving the overall efficiency of semiconductor manufacturing processes.

According to one aspect of the disclosure, a substrate handling assembly is provided. The substrate handling assembly is adapted for use with a substrate container including a container body for accommodating a substrate unit. The substrate handling assembly includes a support member and a handling mechanism. The support member is configured to be disposed inside the container body and configured to support the substrate unit, and the support member includes a clearance portion. The handling mechanism includes a transfer portion and a limiting structure. The transfer portion is movable into and out of the container body and is configured to pick and place the substrate unit in a first axial direction. The limiting structure is disposed on the transfer portion and is configured to positionally limit the substrate unit in a second axial direction. The clearance portion and the limiting structure are structurally complementary to avoid mechanical interference therebetween.

In one embodiment, the transfer portion is movable in the first axial direction to define a pick-up state and a placement state. When the transfer portion is in the pick-up state, the substrate unit is supported by the transfer portion, is separated from the support member, and is positionally limited by the limiting structure. When the transfer portion is in the placement state, the substrate unit is supported by the support member, and the transfer portion and the limiting structure are separated from the substrate unit.

In another embodiment, the clearance portion is an edge recess of the support member in the second axial direction.

In yet another embodiment, the limiting structure includes a limiting plate which is an edge protrusion of the transfer portion in the second axial direction.

In a further embodiment, the limiting structure further includes a limiting block extending from the limiting plate in the first axial direction and configured to contact and position the substrate unit.

In another embodiment, the limiting structure further includes a suction member disposed on the limiting plate and configured to contact and position the substrate unit.

In yet another embodiment, the edge recess is a curved recess or a polygonal recess, and the edge protrusion is a curved protrusion or a polygonal protrusion.

In a further embodiment, the handling mechanism further includes a positioning element disposed on the transfer portion and configured to position the substrate unit in a third axial direction.

In one embodiment, the first axial direction is a vertical direction, and each of the second axial direction and the third axial direction is a horizontal direction orthogonal to the first axial direction.

According to another aspect of the present disclosure, a substrate handling system is provided. The substrate handling system includes a substrate container and a handling mechanism. The substrate container includes a container body and a support member. The container body has an accommodating space therein for accommodating a substrate unit. The support member is disposed on an inner side wall of the container body facing the accommodating space, and the support member is configured to support the substrate unit and includes a clearance portion. The handling mechanism includes a transfer portion and a limiting structure. The transfer portion is movable into and out of the container body and is configured to pick and place the substrate unit in a first axial direction. The limiting structure is disposed on the transfer portion and is configured to positionally limit the substrate unit in a second axial direction. The clearance portion and the limiting structure are structurally complementary to avoid mechanical interference therebetween.

In the substrate handling assembly and the substrate handling system according to the embodiments of the present disclosure, through the structurally complementary design between the clearance portion of the support member and the limiting structure of the handling mechanism, mechanical interference with the support member can be effectively avoided when the handling mechanism enters the container body for pick and place operations of the substrate unit. In addition, by positionally limiting the substrate unit in the second axial direction via the limiting structure, the position of the substrate unit can be stably maintained during the picking, placing, and handling processes, thereby effectively preventing the substrate unit from shifting or wobbling during handling. This not only significantly reduces the risk of stack collapse but also improves the overall safety and efficiency of automated handling operations in semiconductor manufacturing processes.

### BRIEF DESCRIPTION OF DRAWINGS

The present disclosure can be more fully understood by reading the following detailed description of the embodiment, with reference made to the accompanying drawings as follows.

FIG. 1 is a schematic view of a substrate handling assembly according to an embodiment of the present disclosure.

FIG. 2 is a schematic view illustrating the handling mechanism of FIG. 1 when moving into the container body.

FIG. 3 is a schematic view of the handling mechanism and the substrate unit.

FIG. 4 is a schematic view of a clearance portion and a limiting structure according to an embodiment of the present disclosure, illustrating an enlarged view of area P in FIG. 2.

FIG. 5 is a schematic view of a clearance portion and a limiting structure according to another embodiment of the present disclosure.

FIG. 6 is a schematic view of a limiting structure according to another embodiment of the present disclosure.

FIG. 7 is a schematic view of a handling mechanism according to another embodiment of the present disclosure.

FIG. 8 is a schematic view of the transfer portion located inside the container body.

FIG. 9 is a schematic view of the transfer portion contacting the substrate unit after moving.

FIG. 10 is a schematic view of the transfer portion in the pick-up state.

FIG. 11 is a schematic view of a substrate handling system according to an embodiment of the present disclosure.

FIG. 12 is a schematic view of a substrate handling system according to another embodiment of the present disclosure.

FIG. 13 is a schematic view of a substrate handling system according to yet another embodiment of the present disclosure.

### DETAILED DESCRIPTION

According to the substrate handling assembly and the substrate handling system of the embodiments of the present disclosure, the handling mechanism cooperates with the support member inside the substrate container. The clearance portion of the support member and the limiting structure of the handling mechanism are structurally complementary to avoid mechanical interference therebetween. Such configuration enables the handling mechanism to stably pick, place, and handle the substrate unit within the substrate container, preventing the substrate unit from shifting or wobbling during handling, and significantly reducing the risk of stack collapse.

The workpiece in the embodiments of the present disclosure is a substrate unit, which includes a stack of carrier trays and/or substrates. The present disclosure does not limit the number of the carrier trays and/or substrates in the substrate unit. For example, a stack of two or more layers of the substrates and/or the carrier trays can constitute the substrate unit described herein. The substrate is configured to be supported on the carrier tray and may be a thin substrate of various sizes and shapes. Applicable examples include, but are not limited to, a photomask, a wafer, a glass substrate, or other plate-like components related to semiconductor manufacturing processes. During the handling process, the substrate is placed on the carrier tray and is handled, transferred, moved, picked, or placed together with the carrier tray. In this case, the substrate unit includes a stack of a plurality of substrates and carrier trays. However, in some other cases, the carrier tray may be handled, transferred, moved, picked, or placed independently without supporting the substrate. The substrate unit is a stack of multiple carrier trays.

Hereinafter, the embodiments of the present disclosure will be described in detail with reference to accompanying drawings.

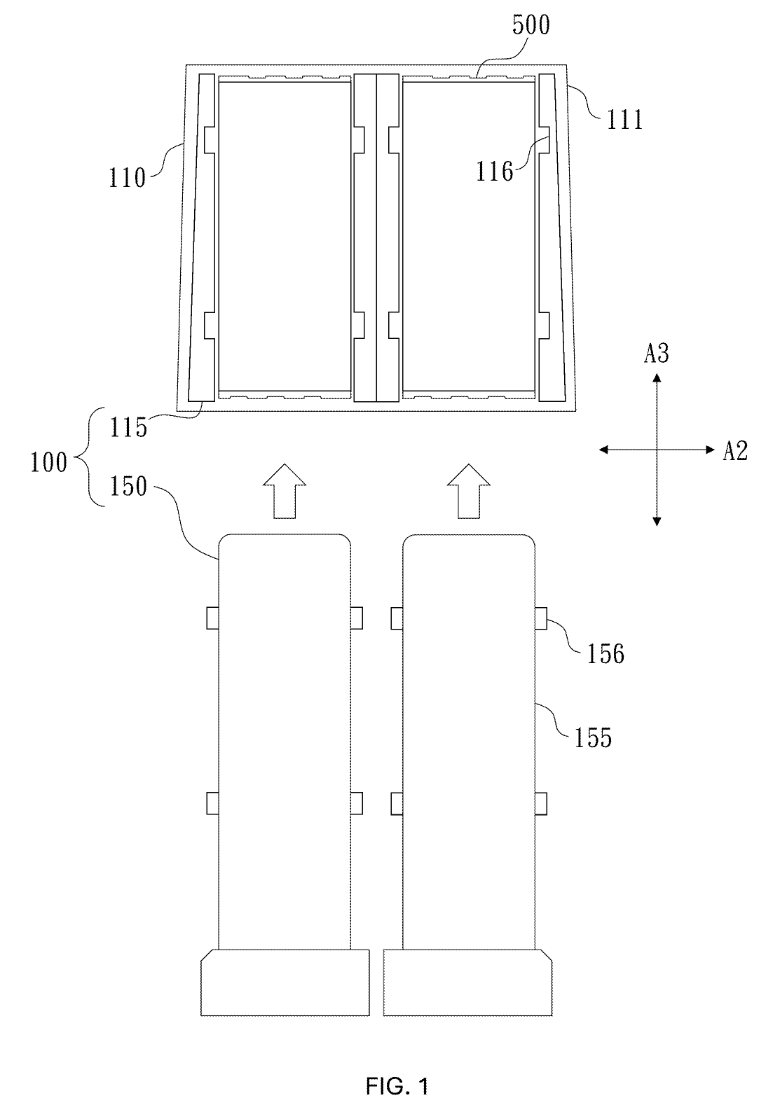

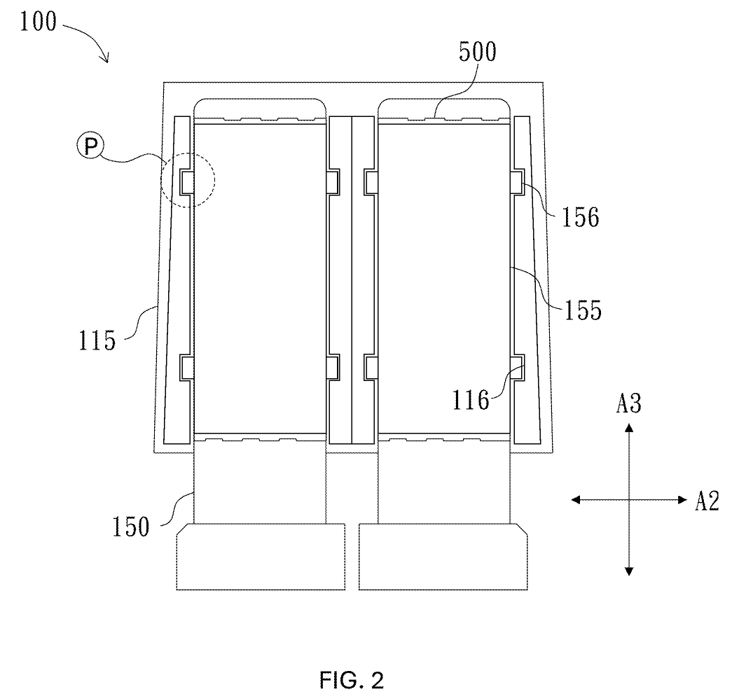

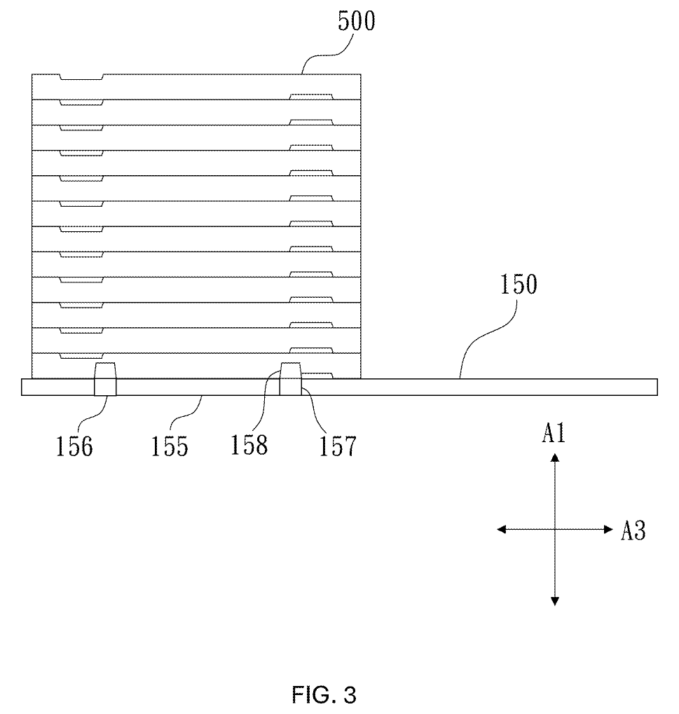

Please refer to FIGS. 1 to 3. FIG. 1 is a schematic view of a substrate handling assembly according to an embodiment of the present disclosure. FIG. 2 is a schematic view illustrating the handling mechanism of FIG. 1 when moving into the container body. FIG. 3 is a schematic view of the handling mechanism and the substrate unit. The substrate handling assembly 100 of the present embodiment is adapted for use with a substrate container 110, and the substrate container 110 includes a container body 111 for accommodating a substrate unit 500. The substrate handling assembly 100 includes a support member 115 and a handling mechanism 150. The support member 115 is disposed inside the container body 111 to support the substrate unit 500 and the support member 115 includes a clearance portion 116. The handling mechanism 150 includes a transfer portion 155 and a limiting structure 156. The transfer portion 155 is movable into and out of the container body 111 and is configured to pick and place the substrate unit 500 in a first axial direction A1. The limiting structure 156 is disposed on the transfer portion 155 and is configured to positionally limit the substrate unit 500 in a second axial direction A2. The clearance portion 116 and the limiting structure 156 are structurally complementary to avoid mechanical interference therebetween.

In the present embodiment, the transfer portion 155 is movable into and out of the container body 111 in a third axial direction A3 which is horizontal, and picks and places the substrate unit 500 in the first axial direction A1 which is vertical. As shown in FIGS. 1-3, in the present embodiment, the first axial direction A1 is defined as a vertical direction, and each of the second axial direction A2 and the third axial direction A3 is defined as a horizontal direction orthogonal to the first axial direction A1. With the structurally complementary design of the clearance portion 116 and the limiting structure 156, when the transfer portion 155 moves upward along the first axial direction A1 within the container body 111, the transfer portion 155 is not obstructed by the support member 115. Therefore, the transfer portion 155 can smoothly lift the substrate unit 500 from the support member 115, or place the substrate unit 500 onto the support member 115. The operating states of the transfer portion 155 will be described in detail later.

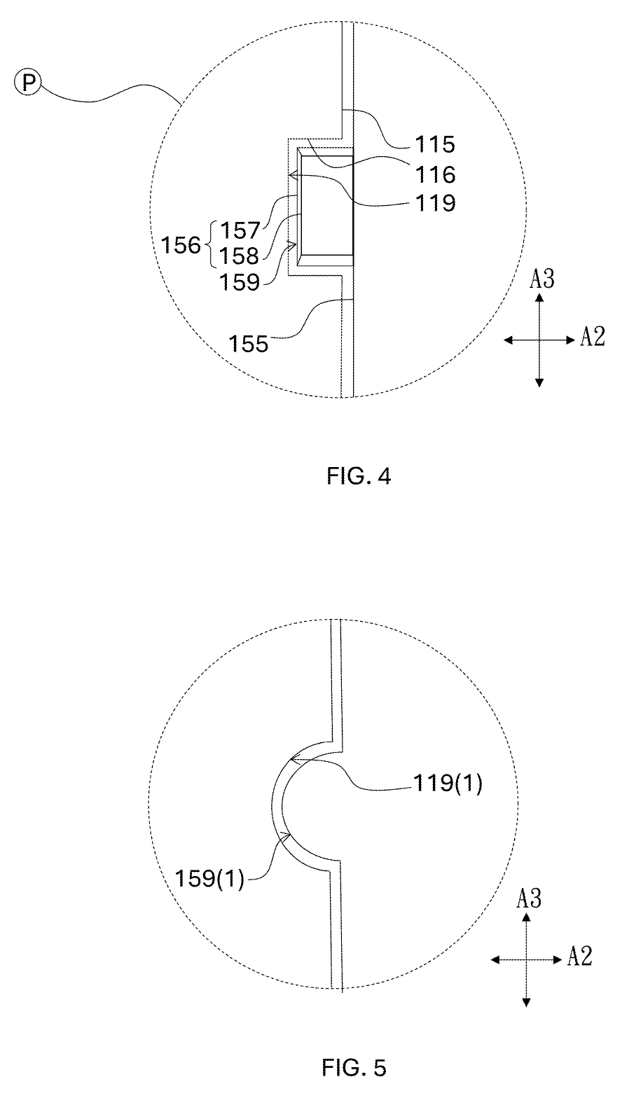

Please refer to FIG. 4, which is a schematic view of a clearance portion and a limiting structure according to an embodiment of the present disclosure. FIG. 4 illustrates an enlarged schematic view of area P in FIG. 2. The clearance portion 116 is an edge recess 119 of the support member 115 in the second axial direction A2. The limiting structure 156 includes a limiting plate 157, which is an edge protrusion 159 of the transfer portion 155 in the second axial direction A2. Due to the structural correspondence (including contour shapes and dimensions) between the edge recess 119 and the edge protrusion 159, mechanical interference between the transfer portion 155 and the support member 115 can be avoided. Thus, the transfer portion 155 can smoothly move vertically along the first axial direction A1, thereby solving the problem of a conventional support member obstructing the movement of a robotic arm. In the present embodiment, the edge recess 119 is a polygonal recess (shown as a rectangle in FIG. 4), and the edge protrusion 159 is a polygonal protrusion (shown as a rectangle in FIG. 4). However, the shapes of the edge recess 119 and the edge protrusion 159 are not limited thereto. Please refer to FIG. 5, which is a schematic view of a clearance portion and a limiting structure according to another embodiment of the present disclosure. In the present embodiment, the edge recess 119(1) is a curved recess, and the edge protrusion 159(1) is a curved protrusion. Due to the structural correspondence (including contour shapes and dimensions) between the edge recess 119(1) and the edge protrusion 159(1), mechanical interference can be avoided as well. A person skilled in the art should understand that the technical solution of the structurally complementary design described herein is not limited to the designs of FIGS. 4 and 5; any other shape configurations that can avoid mechanical interference therebetween can be implemented in the present disclosure.

Next, the technical details of the limiting structure 156 positionally limiting the substrate unit 500 will be described. Please refer to FIGS. 2-4. In addition to the aforementioned limiting plate 157, the limiting structure 156 further optionally includes a limiting block 158. The limiting block 158 extends from the limiting plate 157 in the first axial direction A1 and is configured to contact and position the substrate unit 500. As shown in FIG. 3, in the present embodiment, the limiting block 158 extends upward along the first axial direction A1 to the substrate unit 500, so as to positionally limit the substrate unit 500 in the second axial direction A2 from both sides of the substrate unit 500. This prevents the substrate unit 500 from laterally shifting or wobbling during the handling process, thereby avoiding a situation where the stack of the substrate unit 500 collapses.

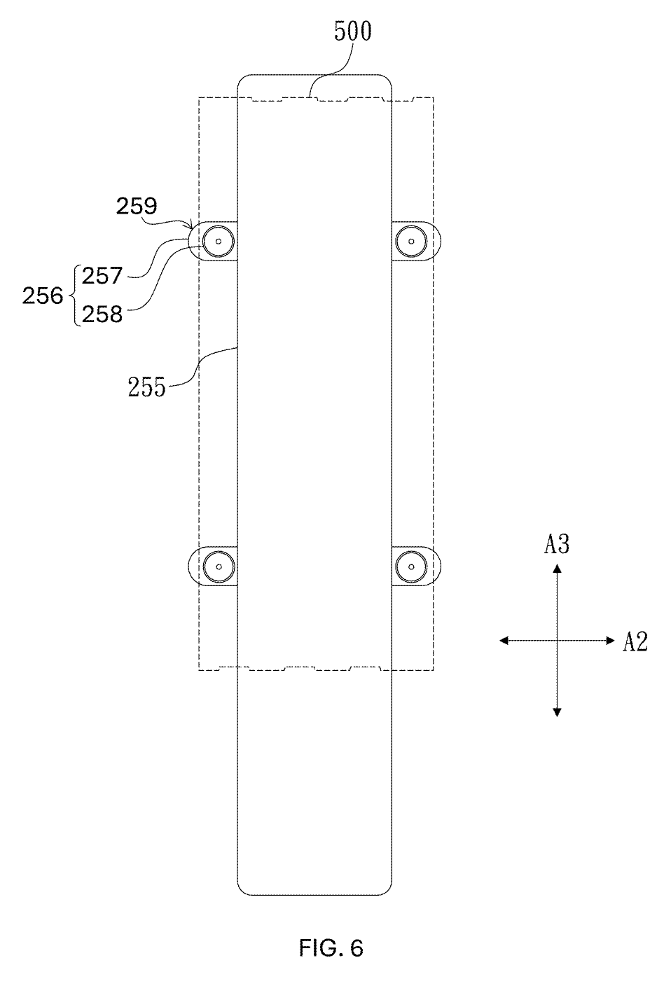

Please refer to FIG. 6, which is a schematic view of a limiting structure according to another embodiment of the present disclosure. In the present embodiment, the limiting structure 256 is disposed on the transfer portion 255 and is configured to positionally limit the substrate unit 500 in the second axial direction A2. The limiting structure 256 includes a limiting plate 257, which is an edge protrusion 259 of the transfer portion 255 in the second axial direction A2. The limiting structure 256 of the present embodiment further includes a suction member 258 which is disposed on the limiting plate 257 and is configured to contact and position the substrate unit 500. In practical applications, the suction member 258 contacts the substrate unit 500 from below in the first axial direction A1 (the vertical direction), and attaches and stably secures the substrate unit 500 by a vacuum force, thereby preventing the substrate unit 500 from laterally shifting or wobbling during the handling process.

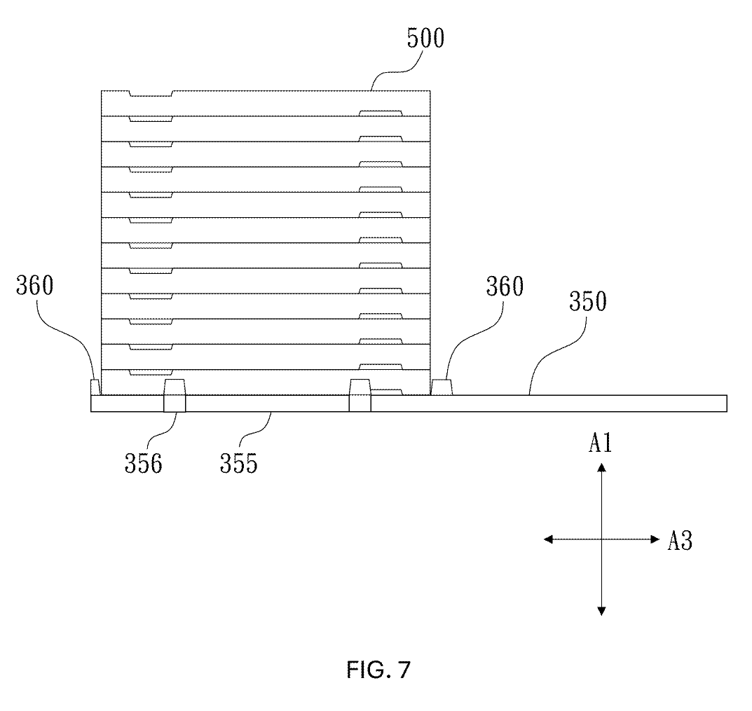

Please refer to FIG. 7, which is a schematic view of a handling mechanism according to another embodiment of the present disclosure. The difference between the handling mechanism 350 of the present embodiment and the aforementioned handling mechanism 150 corresponding to the embodiment of FIG. 3 is that, the handling mechanism 350 of the present embodiment further includes a positioning element 360 disposed on the transfer portion 355 and configured to position the substrate unit 500 in a third axial direction A3 (a horizontal direction orthogonal to the first axial direction A1 and perpendicular to the second axial direction A2). When the transfer portion 355 moves into and out of the container body 111 (container body 111 is shown in FIG. 1) in the third axial direction A3, the positioning element 360 can position the substrate unit 500 on the transfer portion 355. Due to the structural cooperation between the limiting structure 356 and the positioning element 360, the stability of the substrate unit 500 during the movement and transfer processes can be ensured.

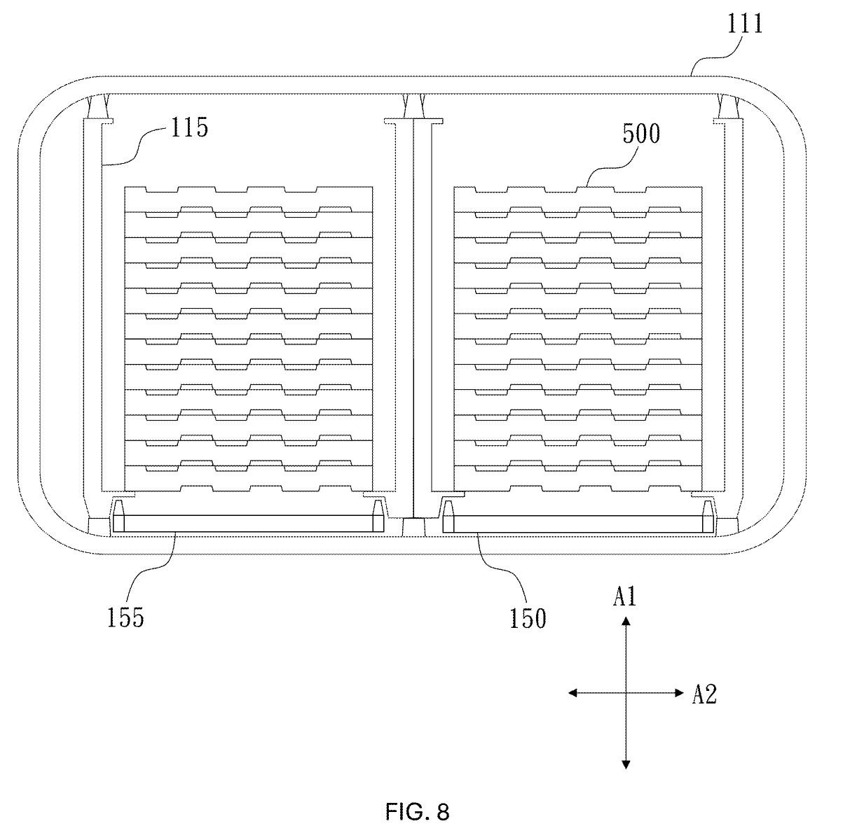

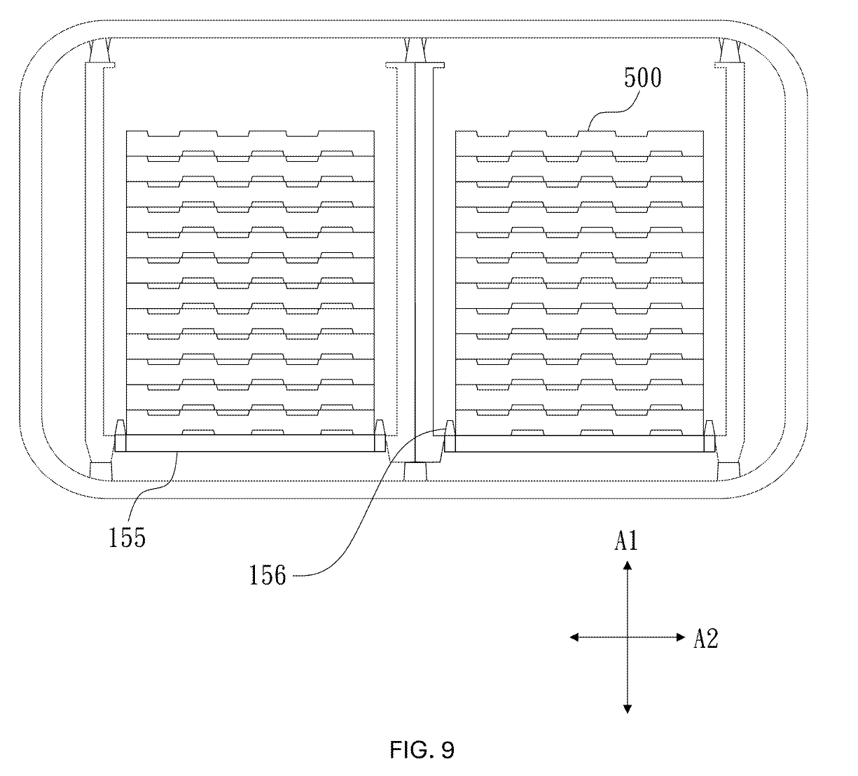

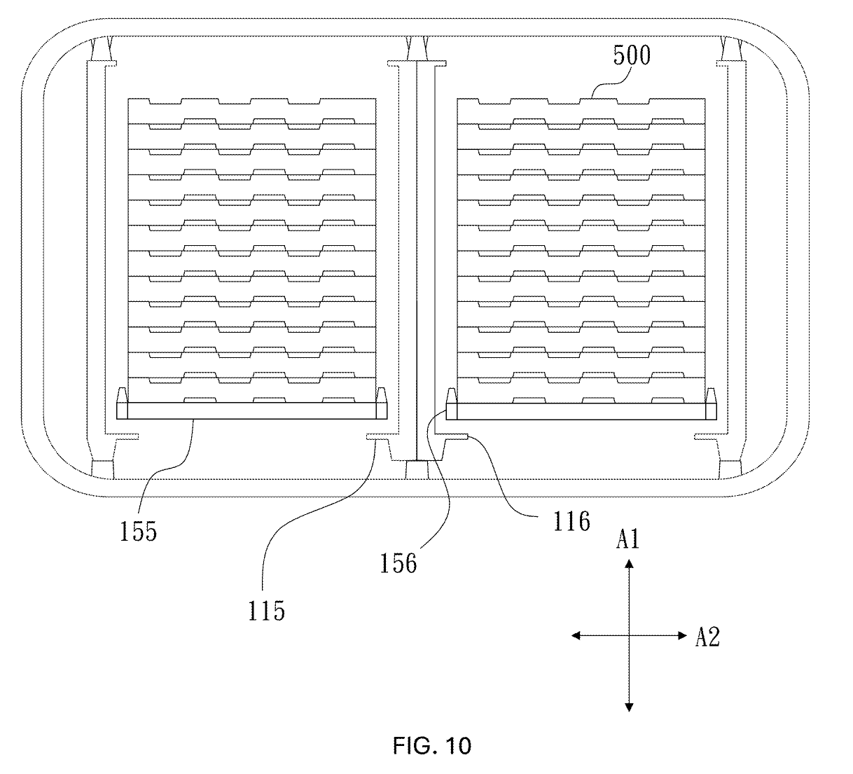

Regarding the operating states of the transfer portion 155 of the aforementioned embodiment, please refer to FIGS. 1-3 and 8-10 at the same time. FIG. 8 is a schematic view of the transfer portion located inside the container body. FIG. 9 is a schematic view of the transfer portion contacting the substrate unit after moving. FIG. 10 is a schematic view of the transfer portion in the pick-up state. The transfer portion 155 of the handling mechanism 150 is movable in the first axial direction A1 to define a pick-up state and a placement state. When the substrate unit 500 is to be handled, first, the transfer portion 155 moves in the third axial direction A3 to enter the container body 111 and reach a predetermined position, as shown in FIGS. 2 and 8. At this time, the transfer portion 155 has not yet contacted the substrate unit 500, and the substrate unit 500 is still supported by the support member 115.

Then, the transfer portion 155 moves upward along the first axial direction A1 until it contacts the substrate unit 500. At this time, the limiting structure 156 is located on both sides of the substrate unit 500.

Subsequently, when the transfer portion 155 continues to move upward along the first axial direction A1 and lifts the substrate unit 500, the transfer portion 155 is in the pick-up state. Due to the structural correspondence between the clearance portion 116 and the limiting structure 156, mechanical interference therebetween is avoided, such that the transfer portion 155 can smoothly lift the substrate unit 500. At this time, the substrate unit 500 is supported by the transfer portion 155 and is separated from the support member 115. The substrate unit 500 is positionally limited by the limiting structure 156 spatially (particularly in the second axial direction A2).

Finally, the transfer portion 155 moves out of the container body 111 along the third axial direction A3, thereby completing the handling operation of removing the substrate unit 500 from the substrate container 110.

Conversely, when the substrate unit 500 is to be moved into the substrate container 110, first, the transfer portion 155 carrying (or supporting, or gripping) the substrate unit 500 moves into the container body 111 along the third axial direction A3 and reaches a predetermined position. Next, the transfer portion 155 moves downward along the first axial direction A1 until the substrate unit 500 contacts the support member 115. When the transfer portion 155 continues to move downward along the first axial direction A1, the substrate unit 500 is solely supported by the support member 115, as both the transfer portion 155 and the limiting structure 156 are separated from the substrate unit 500. At this time, the transfer portion 155 is in the placement state. Finally, the transfer portion 155 exits the container body 111, completing the handling operation of placing the substrate unit 500 into the substrate container 110.

Through the aforementioned structural configuration and operation, when the transfer portion 155 is in the pick-up state, the substrate unit 500 is supported by the transfer portion 155, is separated from the support member 115, and is positionally limited by the limiting structure 156. When the transfer portion 155 is in the placement state, the substrate unit 500 is supported by the support member 115, and the transfer portion 155 and the limiting structure 156 are separated from the substrate unit 500. When handling a stack of multiple substrate units 500, the substrate handling assembly 100 of the present disclosure can significantly reduce the risk of the stack shifting, wobbling, or collapsing, and can improve the overall efficiency of semiconductor manufacturing processes.

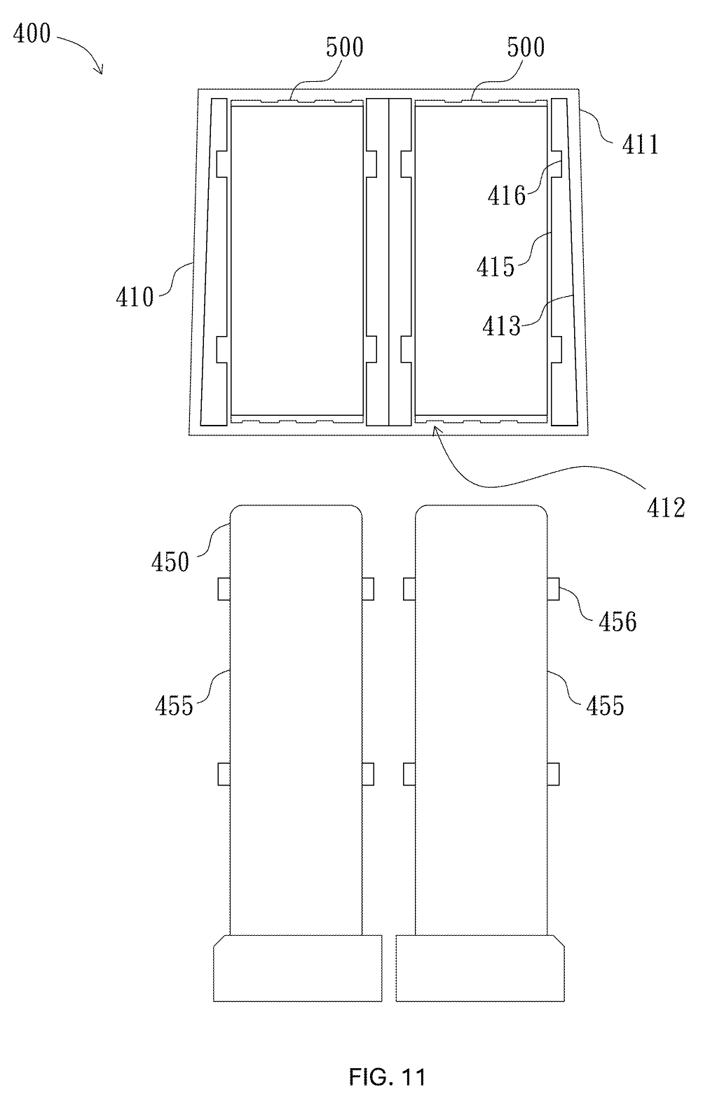

Please refer to FIG. 11, which is a schematic view of a substrate handling system according to an embodiment of the present disclosure. The substrate handling system 400 of the present embodiment includes a substrate container 410 and a handling mechanism 450. The substrate container 410 includes a container body 411 and a support member 415. The container body 411 has an accommodating space 412 therein for accommodating a substrate unit 500. The support member 415 is disposed on an inner side wall 413 of the container body 411 facing the accommodating space 412 to support the substrate unit 500. The support member 415 has a clearance portion 416. The handling mechanism 450 includes a transfer portion 455 and a limiting structure 456. The transfer portion 455 is movable into and out of the container body 411 and is configured to pick and place the substrate unit 500 in a first axial direction A1. The limiting structure 456 is disposed on the transfer portion 455 and is configured to positionally limit the substrate unit 500 in a second axial direction A2. The clearance portion 416 and the limiting structure 456 are structurally complementary to avoid mechanical interference therebetween.

The technical features, such as the structurally complementary design of the clearance portion 416 and the limiting structure 456 and operating states of the transfer portion 455 in the present embodiment, are the same as those of the substrate handling assembly 100 according to the aforementioned embodiments of the present disclosure, and their details will not be repeatedly described herein. By the limiting structure 456 positionally limiting the substrate unit 500 in the second axial direction A2, and by the design that avoids mechanical interference between the clearance portion 416 and the limiting structure 456, the substrate handling system 400 of the present disclosure can significantly reduce the risk of the stack shifting, wobbling, or collapsing, and can improve the overall efficiency of semiconductor manufacturing processes.

Although in the substrate handling system 400 of the present embodiment, the substrate container 410 accommodates two stacks of substrate units 500 as an example (the two stacks of substrate units 500 arranged left and right in FIG. 11), and includes two transfer portions 455 respectively corresponding to handle the two stacks of substrate units 500 as an example, the number of stacks of the substrate units 500 is not limited in the present disclosure.

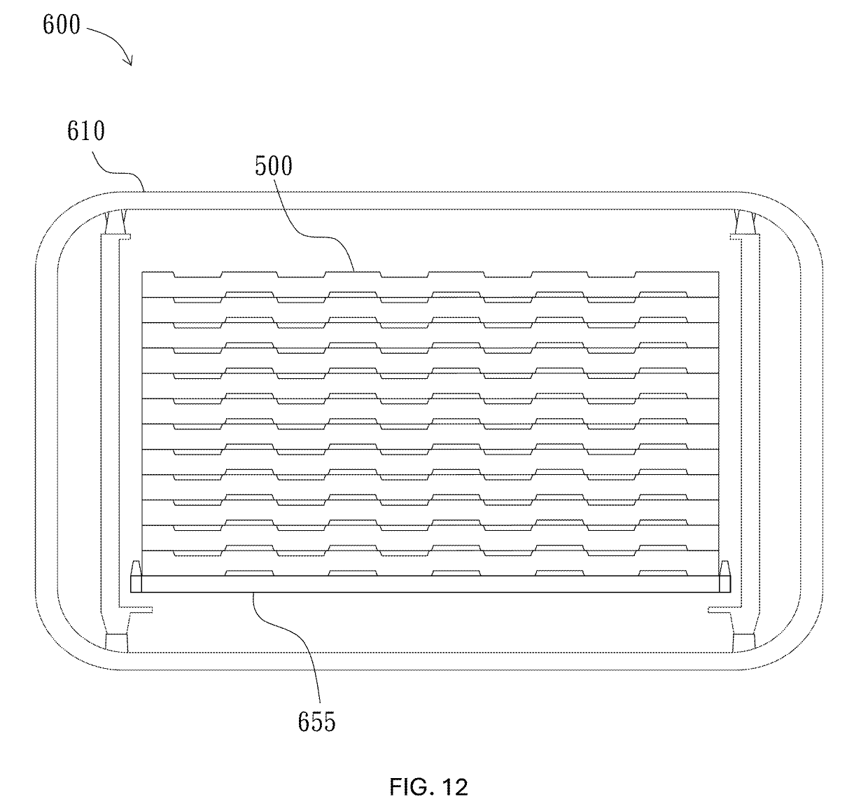

Please refer to FIG. 12, which is a schematic view of a substrate handling system according to another embodiment of the present disclosure. In the substrate handling system 600, the substrate container 610 accommodates, for example, a single stack of the substrate unit 500, and the substrate handling system 600 includes, for example, a single transfer portion 655 to handle the substrate unit 500.

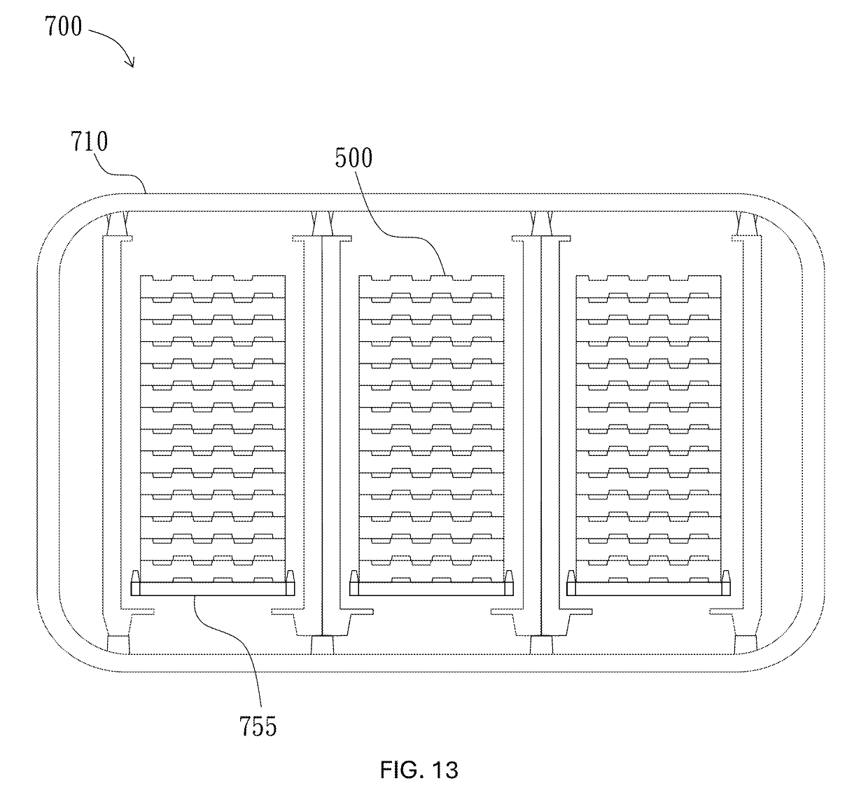

In addition, please refer to FIG. 13, which is a schematic view of a substrate handling system according to yet another embodiment of the present disclosure. In the substrate handling system 700, the substrate container 710 accommodates, for example, three stacks of substrate units 500, and the substrate handling system 700 correspondingly includes three transfer portions 755 to respectively handle the three stacks of substrate units 500.

In the substrate handling assembly and the substrate handling system according to the embodiments of the present disclosure, the substrate handling assembly includes a support member and a handling mechanism. The support member is disposed inside the container body to support the substrate unit and has a clearance portion. The handling mechanism includes a transfer portion and a limiting structure. The transfer portion is movable into and out of the container body and is configured to pick and place the substrate unit in a first axial direction. The limiting structure is disposed on the transfer portion and is configured to positionally limit the substrate unit in a second axial direction. Through the cooperation between the clearance portion of the support member and the limiting structure of the handling mechanism, the substrate unit in the substrate container can be stably picked, placed, and handled, thereby effectively reducing the risk of stack collapse and improving the overall automation efficiency of semiconductor manufacturing processes.

Although the present disclosure has been disclosed with reference to the above embodiments, they are not intended to limit the present disclosure. It will be apparent to those skilled in the art that various modifications and variations can be made without departing from the spirit and scope of the present disclosure. Therefore, the protection scope of the present disclosure shall be defined by the appended claims and their equivalents.

What is claimed is:

1. A substrate handling assembly, adapted for use with a substrate container comprising a container body for accommodating a substrate unit, the substrate handling assembly comprising:
a support member configured to be disposed inside the container body and configured to support the substrate unit, the support member comprising a clearance portion; and
a handling mechanism comprising:
a transfer portion movable into and out of the container body and configured to pick and place the substrate unit in a first axial direction; and
a limiting structure disposed on the transfer portion and configured to positionally limit the substrate unit in a second axial direction;
wherein the clearance portion and the limiting structure are structurally complementary to avoid mechanical interference therebetween.

2. The substrate handling assembly according to claim 1, wherein the transfer portion is movable in the first axial direction to define a pick-up state and a placement state, wherein:
when the transfer portion is in the pick-up state, the substrate unit is supported by the transfer portion, is separated from the support member, and is positionally limited by the limiting structure; and
when the transfer portion is in the placement state, the substrate unit is supported by the support member, and the transfer portion and the limiting structure are separated from the substrate unit.

3. The substrate handling assembly according to claim 1, wherein the clearance portion is an edge recess of the support member in the second axial direction.

4. The substrate handling assembly according to claim 3, wherein the limiting structure comprises a limiting plate which is an edge protrusion of the transfer portion in the second axial direction.

5. The substrate handling assembly according to claim 4, wherein the limiting structure further comprises a limiting block extending from the limiting plate in the first axial direction and configured to contact and position the substrate unit.

6. The substrate handling assembly according to claim 4, wherein the limiting structure further comprises a suction member disposed on the limiting plate and configured to contact and position the substrate unit.

7. The substrate handling assembly according to claim 4, wherein the edge recess is a curved recess or a polygonal recess, and the edge protrusion is a curved protrusion or a polygonal protrusion.

8. The substrate handling assembly according to claim 1, wherein the handling mechanism further comprises a positioning element disposed on the transfer portion and configured to position the substrate unit in a third axial direction.

9. The substrate handling assembly according to claim 8, wherein the first axial direction is a vertical direction, and each of the second axial direction and the third axial direction is a horizontal direction orthogonal to the first axial direction.

10. A substrate handling system, comprising:
a substrate container comprising:
a container body having an accommodating space therein for accommodating a substrate unit; and
a support member disposed on an inner side wall of the container body facing the accommodating space, the support member being configured to support the substrate unit and comprising a clearance portion; and
a handling mechanism comprising:
a transfer portion movable into and out of the container body and configured to pick and place the substrate unit in a first axial direction; and
a limiting structure disposed on the transfer portion and configured to positionally limit the substrate unit in a second axial direction;
wherein the clearance portion and the limiting structure are structurally complementary to avoid mechanical interference therebetween.
